(19) United States
(12) Patent Application Publication
(10) Pub. No.: US 2024/0386157 A1
(43) Pub. Date: Nov. 21, 2024

(54) MANAGEMENT SYSTEM AND MANAGEMENT METHOD

(71) Applicant: Proterial, Ltd., Tokyo (JP)

(72) Inventors: Noriyuki NOZAWA, Tokyo (JP); Shuho KOSEKI, Tokyo (JP); Masami KAMIBAYASHI, Tokyo (JP); Ippei HINOKI, Tokyo (JP); Tomomu ISHIKAWA, Tokyo (JP); Kosuke MATOBA, Tokyo (JP); Koh KAJII, Tokyo (JP)

(73) Assignee: Proterial, Ltd., Tokyo (JP)

(21) Appl. No.: 18/690,116

(22) PCT Filed: Dec. 7, 2022
(86) PCT No.: PCT/JP2022/045185

§ 371 Date: Mar. 7, 2024

(30) Foreign Application Priority Data
Dec. 10, 2021 (JP) 2021-201140

(51) Int. Cl. G06F 30/17

(52) U.S. Cl. CPC G06F 30/17

(57) ABSTRACT

The present invention relates to a management system that manages procurement of a component of a product, the management system including a simulator that simulates molding the component using a 3D printer by a processor executing a program stored in a memory, wherein the simulator is configured to: calculate an evaluation of a spare component; and determine whether the spare component is applicable to the product until a genuine component is procured by comparing procurement of the spare component with procurement of the genuine component based on the evaluation, and present the applicable spare component.

### TECHNICAL FIELD

The present invention relates to a management system and a management method, and more particularly, to a management system and a management method for managing procurement of a component of a product.

### BACKGROUND ART

In mechanical equipment that needs to be operated for a long period of time at a high operation rate, such as a railway and a construction machine, it is important to manage component procurement for suppressing the downtime of the machine associated with component replacement. From the viewpoint of effective use of resources and the like, not only new components but also recycled components are widely used. For example, Patent Literature 1 discloses a device that creates a component procurement plan on the basis of stock information on recycled components and new components.

### CITATION LIST

### Patent Literature

Patent Literature 1: JP 2003-058222 A

### SUMMARY OF INVENTION

### Technical Problem

Meanwhile, in the maintenance of long-term use equipment such as the above-mentioned construction machines or the railways, there are increasing opportunities that components are procured on demand. There is a demand for faster and more reliable quality maintenance. As disclosed in Patent Literature 1, the component procurement based on the stock information on recycled components and new components is not satisfactory in terms of delivery time and durability.

An object of the present invention is to provide a management system and a management method capable of supporting a user in integrally managing component procurement by combining procurement of components using a 3D printer and procurement of genuine components such as new components, recycled components, and recovered components.

### Solution to Problem

The present invention has been made by focusing on the fact that there is a possibility that a machine can be restored earlier than a case where a new component or a regenerated component is manufactured by manufacturing or repairing a component that has suddenly failed on demand, using a 3D printer whose performance has been improved in recent years, near an area where the machine is operating.

That is, the present invention provides a management system that manages procurement of a component of a product, the management system including a processor that executes a program stored in a memory, wherein the processor is configured to: simulate molding the component using a 3D printer; calculate an evaluation of a spare component based on the simulation, the spare component being a component molded by the 3D printer while a component manufactured without depending on the 3D printer is defined as a genuine component; and determine whether the spare component is applicable to the product until the genuine component is procured by comparing procurement of the spare component with procurement of the genuine component based on the evaluation, and present the applicable spare component. The present invention further provides a method for the above-described management.

### Advantageous Effects of Invention

According to the present invention, it is possible to provide a management system and a management method capable of supporting a user in integrally managing component procurement by combining procurement of components using a 3D printer and procurement of genuine components such as new components, recycled components, and recovered components.

### BRIEF DESCRIPTION OF DRAWINGS

FIG. 1 is a functional block diagram of a management system according to the present invention.

FIG. 2 is a flowchart for explaining main operations of the management system illustrated in FIG. 1.

FIG. 3 is a functional block diagram focusing on input and output of data in the management system.

FIG. 4 illustrates a flowchart of operations of a molding simulator.

FIG. 5 is an example of a molding condition list of FIG. 1.

FIG. 6 is a flowchart according to an example of an operation of a determination module of FIG. 1.

FIG. 7 is an example of a procurement method list of FIG. 1.

FIG. 8 is another example of the procurement method list.

### DESCRIPTION OF EMBODIMENTS

Next, an embodiment of the present invention will be described. A component that has suddenly failed near an area where a machine is operating, e.g., a mold, can be manufactured on demand using a 3D printer whose performance has been improved in recent years and is procured at an early stage, and can be used as a berthed spare component until a genuine component manufactured according to a normal method such as a mold manufacturing process is procured, thereby more quickly resuming the operation of the manufacturing device. Therefore, the management system according to the present invention can improve component procuring efficiency by combining the procurement of a spare component and the procurement of a genuine component manufactured by a mold manufacturing process or the like without depending on a 3D printer, and then suppress the downtime of the product.

Although a component can be procured quickly by using a 3D printer, an attempt to manufacture a high-quality component may result in a longer delivery time and a higher cost. On the other hand, an attempt to improve the component manufacturing efficiency by placing importance on the delivery time and the cost, may result in that the durability of the component is highly likely to be inferior to a durability of a new genuine component. In addition, if the spare component has an insufficient durability to withstand practical use until a new component is procured, a failure of the component may recur in a short period of time before the new component is procured, and there is a possibility that the downtime of the machine may not be shortened in the long run. In this respect, the management system according to the present invention supports a user's attempt to integrally manage component procurement by combining spare component procurement and genuine component procurement.

The present management system evaluates a spare component by simulating the molding of the spare component using a 3D printer (hereinafter, a metal 3D printer will be described as an example), and provides a user with a support for optimizing component procurement combining the spare component and the new component on the basis of a result of the evaluation. Hereinafter, the management system will be described in detail with reference to the drawings.

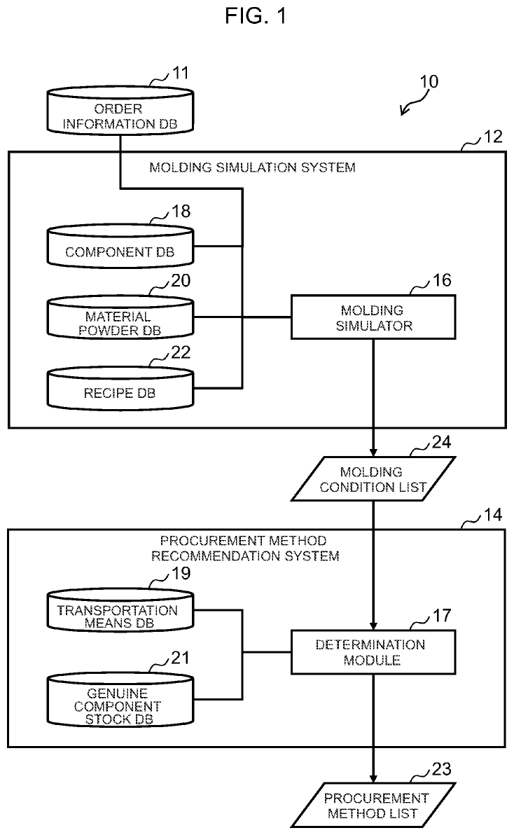

The management system 10 realizes a functional block configuration illustrated in FIG. 1 by using normal hardware resources such as a processor such as a CPU, a memory, a storage, and a network, and software resources such as an OS and an application. In addition, the processor executes a management method set forth in the claims according to the functional block illustrated in FIG. 1.

In FIG. 1, the management system 10 includes a molding simulation system 12 that simulates a molding process of a metal 3D printer and a procurement method recommendation system 14 that recommends how to procure a component to a user.

The molding simulation system 12 includes a molding simulator 16 as a module that simulates a molding process of a metal 3D printer, and further includes a component database (DB) 18 in which specifications of components such as shapes, sizes, and materials of the components are recorded, a material powder DB 20 in which a plurality of molding materials are stored, and a molding recipe DB 22 in which a plurality of molding recipes are recorded. An order information DB 11 exists on the side of the user who orders a component, and records various request information related to the component to be ordered, such as a component name, a component ID, and a requested delivery date. As will be described below, the molding simulator 16 outputs a molding condition list 24 for enabling the molding of the component to the procurement method recommendation system 14, using the order information DB 11, the component DB 18, the material powder DB 20, and the molding recipe DB 22. At this time, the processor realizes a functional means as the molding simulator 16 by executing a program.

The procurement method recommendation system 14 includes a determination module 17 for recommending a procurement method to the user, and further includes a transportation means DB 19 that stores transportation mediums, such as a truck, a railway, and an airplane, the number of days of transportation to a component transportation destination, and the like, and a genuine component stock DB 21 that records whether genuine components are in stock, the genuine components being not manufactured as substitute components by a metal 3D printer, such as new components, recycled components, and recovered components that are actual components not manufactured by the metal 3D printer, locations where the genuine components are stored, manufacturers of the actual components, and the like. The determination module 17 outputs a procurement method list 23 using the transportation means DB 19 and the genuine component stock DB 21 as will be described below. At this time, the processor realizes a functional means as the determination module 17 by executing a program.

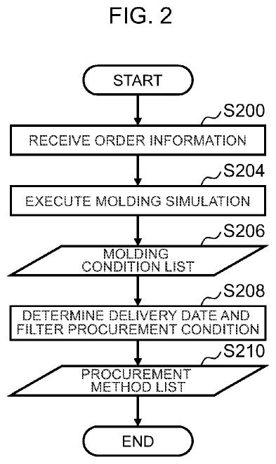

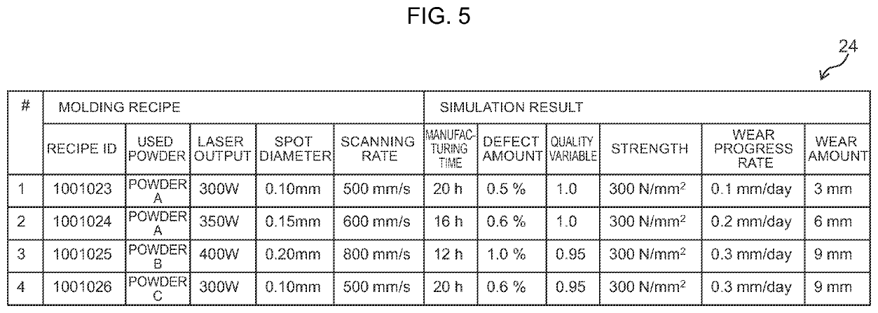

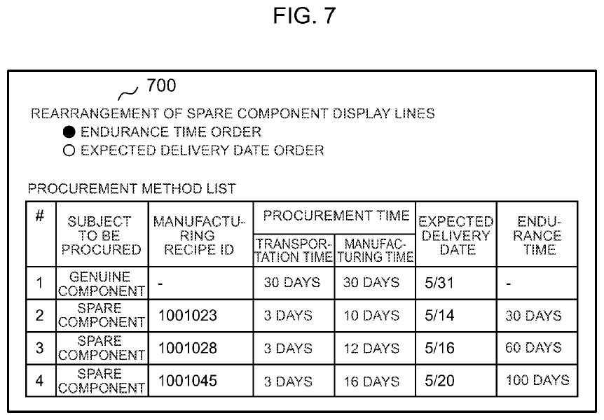

FIG. 2 is a flowchart of main operations of the management system. The processor of the management system 10 searches the order information DB 11 every predetermined timing, and starts the flowchart of FIG. 2 when it is determined that there is a new order request. After receiving order information from the order information DB 11 (S200), the management system 10 causes the molding simulator 16 to execute a molding simulation (S204), and output a molding condition list 24 (FIG. 5) to the determination module 17 (S206). Next, the management system 10 causes the determination module 17 to determine a delivery and filter a procurement condition (S208), and further causes the determination module 17 to output a procurement method list 23 (FIG. 7) to the user (S210).

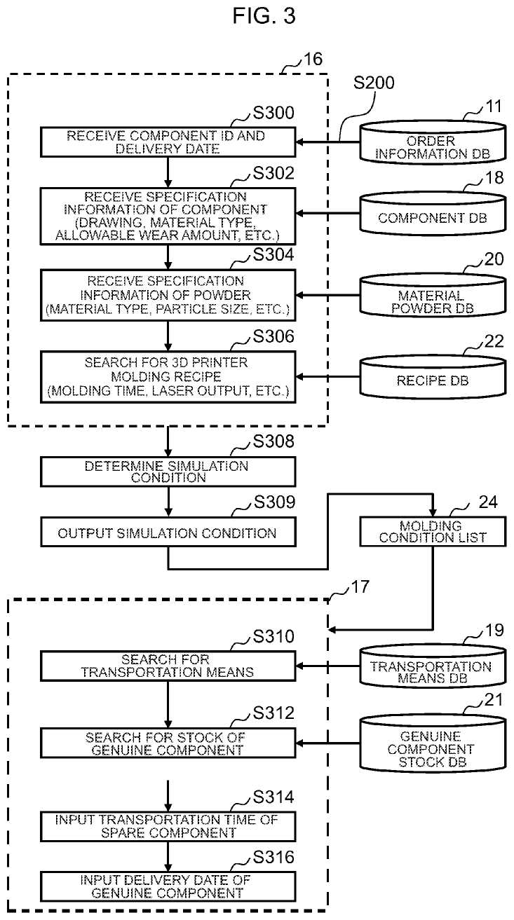

FIG. 3 is a functional block diagram focusing on input and output of data in the management system. When receiving an ID of an ordered component and a requested delivery date from the order information DB 11 (S300), the molding simulator 16 receives specification information (drawing, material type, allowable wear information, etc.) of the ordered component from the component DB 18 (S302). Subsequently, the molding simulator 16 receives specification information (material type, particle size, etc.) of powder from the material powder DB 20 for the metal 3D printer (S304), and further searches the molding recipe DB 22 for a molding recipe using the metal 3D printer (molding time, laser output, etc.) (S306).

The molding simulator 16 determines a condition related to the molding simulation based on S302 to S306 (S308), and outputs the determined condition to a molding condition list 24 (S309). The molding simulator 16 outputs the molding condition list 24 to the determination module 17. The determination module 17 searches the transportation means DB 19 for a transportation means (S310), and subsequently searches the genuine component stock DB 21 for a stock of a genuine component (S312). Further, the determination module 17 inputs a result of searching for a transportation means (S310) to a transportation time (S610) of a spare component molded by the metal 3D printer (S310), and inputs a result of searching for a stock of a genuine component (S312) to a procurement time (S606) of a genuine component (S316).

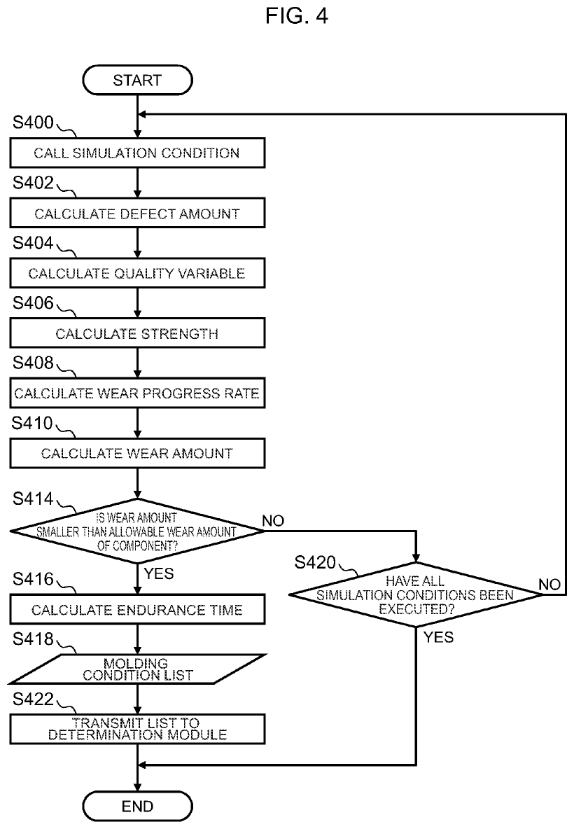

FIG. 4 illustrates a flowchart of operations of the molding simulator 16. The molding simulator 16 calls a simulation condition including a combination of a molding material, a molding recipe, and the like related to a procurement-requested component from the memory (S400), and calculates a durability of a spare component for evaluation in the subsequent steps S402 to S422. As an example, the molding simulator 16 calculates a wear amount of the spare component as an index of durability from the molding material and the molding recipe. Note that the index indicating “durability” is not limited to the wear amount. Depending on what the component is, durability may be indicated by another index such as fatigue fracture, erosion, heat crack, or corrosion.

First, the molding simulator (molding simulation tool) 16 can calculate a void defect amount of a metallic tissue, for example, using a machine learning technique or the like based on the molding material, the laser output, the laser scanning interval, the spot diameter, and the like (S402). Since the defect amount affects a durability of a molded object, the molding simulator 16 calculates a quality variable as an index of quality of the molded object based on the defect amount (S404). The quality variable can be defined as a value obtained by multiplying a variable based on the usage environments and the material characteristics of the component by the defect amount.

The molding simulator 16 calculates a strength of the molded object (component) based on the quality variable (S406), and then calculates a wear progress rate (S408). The wear progress rate may be defined as the product of a certain constant, a quality variable, a load when the component is used/a strength of the component. Next, the molding simulator 16 calculates a wear amount by multiplying the wear rate by an expected usage time of the component (S410).

Next, the molding simulator 16 compares the calculated wear amount with the allowable wear amount related to the component, and determines whether the calculated wear amount is smaller than the allowable wear amount (S414). When the determination is negative, it is determined that a genuine component cannot be substituted with the spare component manufactured by the metal 3D printer, and the process proceeds to S420. Then, the other simulation conditions are repeatedly executed, and it is determined whether all the molding simulation conditions have been executed (420). At this time, the molding simulator 16 ends the flowchart when the determination in S420 is affirmative, and returns to S400 when the determination in S420 is negative.

On the other hand, when the determination in S414 is affirmative, the molding simulator 16 calculates an endurance time of the molded body (S416). The endurance time is a value obtained by dividing the allowed wear amount by the wear progress rate. Next, the molding simulator 16 executes the processing of S402 to S416 for all the simulation conditions, collects the simulation conditions when the determination in S414 is affirmative in the molding condition list (S418), and transmits the molding condition list to the determination module 17 (S422).

An example of the molding condition list 24 is illustrated in FIG. 5. The molding condition list includes a combination of a molding recipe and a simulation result, and including a recipe ID for each molding pattern (#: 1, 2, 3, . . . ) information on a molding recipe and a simulation result are recorded. The information on the molding recipe includes used powder, laser output, spot diameter, and laser scanning rate, and the simulation result includes manufacturing time required for molding, defect amount, quality variable, strength, wear progress rate, and wear amount. For example, in #2, if the laser output is increased, even though powder having the same specification is used, the scanning rate can be increased and the manufacturing time can be shortened. However, on the other hand, the defect amount increases, and the wear progress rate and the wear amount increase. Note that each of the plurality of recipe IDs is one molding condition.

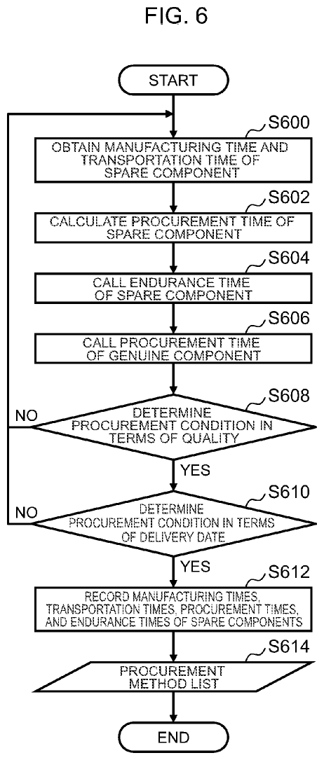

FIG. 6 illustrates an example of the operation (S208 in FIG. 2) of the determination module 17 as a flowchart. In this flowchart, the determination module 17 presents a procurement method as a recommendation in the form of a list for each spare component, that is, for each molding pattern in the molding condition list 24 (this will be described below with reference to FIG. 7).

The determination module 17 reads a manufacturing time of a spare component from the molding condition list 24 (FIG. 5), and obtains a transportation time of the spare component, together with the manufacturing time of the spare component, by referring to the transportation means DB 19 (S600). Next, a time required to procure the spare component is calculated (S602). The procurement time may be obtained by adding the manufacturing time of the spare component and the transportation time of the spare component.

Next, an endurance time of the spare component (FIG. 4: S416) is called (S604). Furthermore, a procurement time of a genuine component is called by referring to the genuine component stock DB 21 and the transportation means DB 19 (S606). In order to evaluate whether it is beneficial to use the spare component before the genuine component is procured, the determination module 17 determines whether to procure the spare component by focusing on the quality of the spare component (S608). In this evaluation, the quality index of the spare component is an endurance time, and the endurance time takes a different value depending on the molding condition. On the other hand, the procurement time of the spare component takes a fixed value regardless of the molding condition. Based on the above, specifically, it is determined whether the sum of the procurement time and the endurance time of the spare component is longer than the procurement time of the genuine component. If the determination is negative, there is no merit in procuring the spare component, and it is determined that the genuine component should be procured. Then, the process returns to S600, and S600 to S608 are repeatedly performed for the other spare components (components specified as the molding patterns (#) in FIG. 5).

When the determination in S608 is affirmative, the determination module 17 determines whether it is appropriate to procure the spare component by focusing on the procurement time, a so-called delivery date, of the spare component (S610). Specifically, it is determined whether the procurement time of the spare component is shorter than the procurement time of the genuine component. When this determination is negative, that is, when the procurement time of the genuine component is shorter than the procurement time of the spare component, there is no merit in procuring the spare component, and it is determined that the genuine component should be procured. Then, the process returns to S600, and S600 to S610 are repeatedly performed for the other spare components. On the other hand, when the determination in S610 is affirmative, the determination module 17 determines that there is a merit in procuring the spare component until the genuine component is procured, and the process proceeds to the recording step (S612).

For all the spare components that have passed through both steps S608 and S610 in an affirmative manner, the determination module 17 records the manufacturing times, the transportation times, the procurement times, and the endurance times of the spare components in the memory (S612), and outputs the recorded information as a procurement method list 23 (S614). Note that S608 and S610 correspond to procurement condition filtering.

FIG. 7 illustrates an example of an output mode of the procurement method list. According to FIG. 7, when a sum of a procurement time (a sum of a manufacturing time and a transportation time) and an endurance time of a spare component is longer than a procurement time (a transportation time) of a genuine component while the procurement time of the spare component is shorter than the procurement time of the genuine component, the spare component is recommended to the user by being presented in the procurement method list as being advantageous when used before the genuine component is procured. As one of the advantages, a genuine component having reliable performance can be used as a component of a product, and the device can be operated using a more reliable spare component that can substitute the genuine component during a period until the genuine component is procured. This advantage is important in order to suppress the downtime as much as possible for what requires a high operation rate, such as a construction machine, a railway vehicle, or a metal mold.

If the spare component is manufactured over time, the endurance time of the spare component increases, but the delivery time of the spare component is delayed because of the manufacturing time. When the procurement time (the sum of the manufacturing time, the transportation time, and the endurance time) of the spare component is shorter than the procurement time (transportation time) of the genuine component, the spare component becomes unusable before the genuine component is delivered, and there is no usable component until the genuine component is delivered, resulting in a non-operated stated of the product. In order to prevent an occurrence of this state, the sum of the procurement time until the spare component is delivered and the endurance time of the spare component is longer than the procurement time until the genuine component is delivered. Among spare components listed in FIG. 7, spare components #3 is more effective than spare components #4, and spare component #2 is more effective than spare components #3, because the expected delivery date is earlier, so that an operating time of the product can be gained by the spare component as much as possible until the genuine component is delivered. Note that, in the procurement method list, the components (genuine components and spare components) in the list can be sorted in order of endurance time or in order of expected delivery date (700 in FIG. 7).

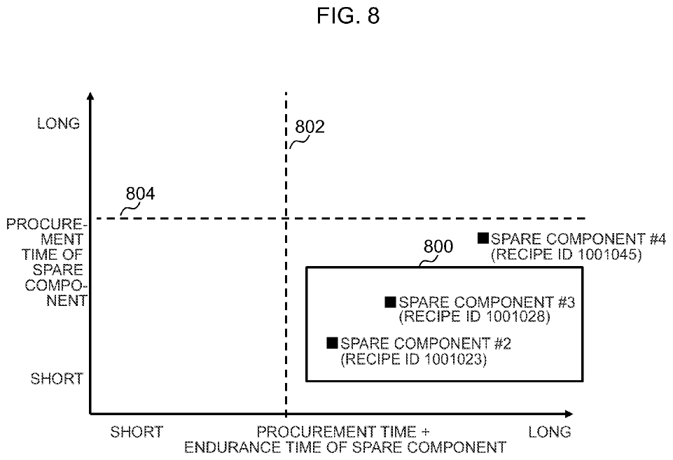

As an output mode of the procurement method list 23, a graph format as illustrated in FIG. 8 may be used rather than a table format as illustrated in FIG. 7. In FIG. 8, the horizontal axis represents a sum of a procurement time and an endurance time of a spare component, and the vertical axis represents a procurement time of a spare component. Then, 802 and 804 indicate a sum of a manufacturing transportation time, which is a procurement time of #1 (genuine component). A plurality of spare components (#2 to #4) applicable to the product are plotted in a preferred region defined by coordinates on the horizontal axis and the vertical axis, that is, a region in which the sum of the procurement time and the endurance time of the spare component is longer than the procurement time of the genuine component, and the procurement time of the spare component is shorter than the procurement time of the genuine component.

An administrator or a user of the management system can select a predetermined spare component from among the plurality of spare components, and request a person concerned to procure the spare component, that is, actually manufacture the spare component and transport the manufactured spare component. For example, the management system recommends, to the user, a spare component that satisfies both an endurance time and an expected delivery date, that is, a spare component within a range of a rectangular region 800 as a recommended procurement method. In a case where there are a plurality of spare components of this type, the user may select a specific spare component by giving priority to the endurance time or the expected delivery date.

The above description is merely an example, and the present invention is not limited to the configuration of the above-described embodiment, and includes various modifications. For example, although it has been described in the above-described embodiment that a spare component is molded by the metal 3D printer, a resin component may be molded by a resin 3D printer.

Furthermore, the present invention does not exclude a configuration in which, even if the sum of the procurement time and the endurance time of the spare component is smaller than the procurement time of the genuine component, the spare component is combined with an additional spare component for application to the product, and more specifically, a configuration in which if it is advantageous, in terms of cost and product uptime, for a certain type of a component that has failed to prepare two or more spare components and apply the two or more spare components to the product while replacing them until the genuine component is delivered, two or more replacements are applied to the product by preparing a plurality of spare components for use until the genuine component is procured.

Furthermore, in a case where a function of predicting a time at which a component will fail based on a product operation record is provided, the present invention does not exclude a configuration in which if it is advantageous, in terms of cost and product uptime, to create a spare component in advance of the predicted time of failure, the time at which the component will fail is added to the procurement method recommendation system (14).

The above-described embodiments have been described in detail to describe the present invention in an easy-to-understand manner, and are not necessarily limited to those having all the described configurations. In addition, a part of a configuration of a certain embodiment can be replaced with a configuration of another embodiment, and a configuration of a certain embodiment can be added to a configuration of another embodiment. In addition, with respect to a part of a configuration of each embodiment, it is possible to add, delete, and substitute another configuration. Furthermore, the steps in the process according to each embodiment may be executed in an appropriately changed order as long as the same result can be obtained.

### REFERENCE SIGNS LIST

10 Management system
11 Order information DB
12 Molding simulation system
14 Procurement method recommendation system
16 Molding simulator 16
17 Determination module
18 Component DB
19 Transportation means DB
20 Material powder DB
21 Genuine component stock DB
22 Molding recipe DB
23 Procurement method list
24 Molding condition list

1. A management system that manages procurement of a component of a product, the management system comprising a processor that executes a program stored in a memory,
wherein the processor is configured to:
simulate molding the component using a 3D printer;
calculate an evaluation of a spare component based on the simulation, the spare component being a component molded by the 3D printer while a component manufactured without depending on the 3D printer is defined as a genuine component; and
determine whether the spare component is applicable to the product until the genuine component is procured by comparing procurement of the spare component with procurement of the genuine component based on the evaluation, and present the applicable spare component.

2. The management system according to claim 1, wherein the processor is configured to:
simulate molding the spare component using the 3D printer;
calculate an endurance time of the spare component as the evaluation based on a molding material and a molding recipe of the 3D printer.

3. The management system according to claim 2, wherein the processor is configured to:
calculate a strength of the spare component based on the molding material and the molding recipe of the 3D printer;
calculate wear of the spare component corresponding to the strength; and
calculate the endurance time corresponding to the calculated wear.

4. The management system according to claim 3, wherein the processor is configured to:
compare the procurement of the spare component with the procurement of the genuine component by comparing a sum of the endurance time and a procurement time of the spare component with a procurement time of the genuine component.

5. The management system according to claim 4, wherein the processor is configured to:
determine that the spare component is applicable to the product during a period until the genuine component is procured when the procurement time of the spare component is shorter than the procurement time of the genuine component.

6. The management system according to claim 4, wherein the processor is configured to:
recommend a user to apply the spare component to the product until the genuine component is procured when the sum of the endurance time and the procurement time of the spare component is longer than the procurement time of the genuine component.

7. The management system according to claim 4, wherein the procurement time of the spare component is a sum of a manufacturing time taken to mold the spare component using the 3D printer and a transportation time.

8. A management method for managing procurement of a component of a product, the management method comprising, by a processor executing a program stored in a memory:
simulating molding the component using a 3D printer;
calculating an evaluation of a spare component based on the simulation, the spare component being a component molded by the 3D printer while a component manufactured without depending on the 3D printer is defined as a genuine component; and
determining whether the spare component is applicable to the product until the genuine component is procured by comparing procurement of the spare component with procurement of the genuine component based on the evaluation, and presenting the applicable spare component.
